(19) United States
(12) Patent Application Publication
(10) Pub. No.: US 2022/0328617 A1
(43) Pub. Date: Oct. 13, 2022

(54) FIELD EFFECT TRANSISTOR AND METHOD FOR MANUFACTURING THE SAME

(71) Applicant: Silergy Semiconductor Technology (Hangzhou) Ltd., Hangzhou City (CN)

(72) Inventors: Xianguo Huang, Hangzhou City (CN); Xunyi Song, Hangzhou City (CN); Meng Wang, Hangzhou City (CN)

(21) Appl. No.: 17/850,268

(22) Filed: Jun. 27, 2022

Related U.S. Application Data
(63) Continuation of application No. 16/246,039, filed on Jan. 11, 2019.

(30) Foreign Application Priority Data
Jan. 12, 2018 (CN) 201810028656.2

(51) Int. Cl. H01L 29/06; H01L 21/265; H01L 29/66; H01L 27/06; H01L 29/78; H01L 29/10

(52) U.S. Cl. CPC H01L 29/0603; H01L 21/265; H01L 29/66045; H01L 27/0623; H01L 29/78; H01L 29/1083; H01L 29/1087

(57) ABSTRACT

Disclosed is a field effect transistor (FET) and a method for manufacturing the same, the FET comprises: a substrate, a first well region located on the substrate, a second well region, a body contact region, a source region, a drain region and a gate conductor. The body contact region, the source region and the drain region are located in the first well region, the doping concentration of the second well region is higher than that of the first well region. A parasitic bipolar junction transistor (BJT) is located in the field effect transistor, current flowing through the BJT is controlled by adjusting doping concentration or area of the second well region. The second well region is formed in the first well region, so that the holding voltage of the FET is improved, and finally effect on the FET caused by the current flowing through the BJT can be weakened.

### CLAIM OF PRIORITY

This application is a continuation application to U.S. patent application Ser. No. 16/246,039, filed on Jan. 11, 2019, entitled “FIELD EFFECT TRANSISTOR AND METHOD FOR MANUFACTURING THE SAME”, and published as US 2019/0237537 on Aug. 1, 2019, which claims priority to Chinese Application No. 201810028656.2, filed on Jan. 12, 2018 (published as CN 108389890 A), the contents of which are hereby incorporated by reference in their entireties.

### BACKGROUND OF THE DISCLOSURE

### Field of the Disclosure

The present disclosure relates to the field of semiconductor technology, and more particularly, to a field effect transistor and a method for manufacturing the same.

### Description of the Related Art

In an integrated circuit, an N-type field effect transistor (FET) is generally used as a power transistor, as shown in FIG. 1a, a parasitic NPN bipolar junction transistor (BJT) is included in an N-type field effect transistor, where drain region 910, source region 920 and P-type well region 930 of the field effect transistor are equivalent to a collector region, an emitter region and a base region of the parasitic NPN bipolar junction transistor, respectively. Due to the existence of the parasitic NPN bipolar junction transistor, a snap-back phenomenon occurs when the FET breaks down, thus a snap-back voltage is generated and the parasitic NPN bipolar junction transistor is turned on when the snap-back phenomenon occurs. At this time, only a relatively low voltage between the source region 920 and the drain region 910 of the N-type FET is required for maintaining a large current flowing through the parasitic NPN bipolar junction transistor, the relatively low voltage is called a holding voltage of the N-type field effect transistor, as shown in FIG. 1b. The current generated by parasitic NPN bipolar junction transistor may flow to a substrate 940 of the FET, leading to the failure of the function of the field effect transistor and even burning the field effect transistor. Thus, a low holding voltage of the N-type FET can greatly reduce a Safe Operating Area (SOA) of the FET, thereby limiting a SOA of a chip.

One way for solving the above-mentioned problem in the prior art is to limit the application voltage of the chip, which obviously reduces the competitiveness of the chip.

Another way is to lengthen the channel of the N-type FET. After the channel of the N-type FET is lengthened, although the amplification of the NPN bipolar junction transistor can be reduced by increasing the width of the base region of the parasitic NPN bipolar junction transistor, the holding voltage can be improved. However, lengthening the channel may greatly increase the resistance of the N-type FET, and the area of the FET is also increased, causing extra cost for manufacturing the FET. Additionally, the effect of lengthening the channel on holding voltage is not obvious.

In summary, how to improve the holding voltage of the N-type FET effectively has become one of the key issues to improve the safe operating area of the FET and the safe operating area of the chip.

### SUMMARY OF THE DISCLOSURE

The technical problem to be solved in the present disclosure is to provide a field effect transistor and a method for manufacturing the same, where a second well region is formed in a first well region for increasing doping concentration of a base region of the parasitic NPN BJT, such that resistance of the base region of the parasitic NPN BJT is reduced, thereby a amplification factor of the parasitic NPN BJT is reduced, the holding voltage of the FET is improved, and parasitic effect of the FET is weakened, and finally, the effect of the holding voltage of the FET on the FET can be reduced.

According to one aspect of the present disclosure, there is provided a field effect transistor, comprising: a substrate; a first well region located on the substrate; a second well region located in the first well region; a body contact region, a source region and a drain region, all of which are located in the first well region, wherein the source region is located between the body contact region and the drain region, wherein a channel is formed between the source region and the drain region; a gate conductor located above the channel between the source region and the drain region; wherein the substrate, the first well region and the body contact region are doped to have a first conductive type, the source region and the drain region are doped to have a second conductive type, doping concentration of the second well region is higher than that of the first well region, the drain region is located in the first well region.

Preferably, a parasitic bipolar junction transistor is located in the field effect transistor, the second well region is configured to reduce resistance of a base region of the parasitic bipolar junction transistor.

Preferably, the second well region is at least located between the body contact region and the source region.

Preferably, a breakdown voltage of the field effect transistor is regulated by adjusting doping concentration of the first well region, and a holding voltage of the field effect transistor is regulated by adjusting doping concentration of the second well region.

Preferably, the first conductive type is one of N type and P type, the second conductive type is the other one of N type and P type.

Preferably, a breakdown position of the field effect transistor is located at a common boundary between the drain region and the first well region.

Preferably, the second well region is located between the body contact region and the source region, the body contact region and the source region are located in the first well region, the gate conductor is located above the first well region.

Preferably, the body contact region is located in the second well region, the source region is located in the first well region, and the gate conductor is located above the first well region.

Preferably, the body contact region is located in the second well region, the source region is located in the first well region and the second well region, and the gate conductor is located above the first well region.

Preferably, the body contact region and the source region are located in the second well region, a side surface of the source region near the gate conductor is close to a side surface of the second well region near the gate conductor, and the gate conductor is located above said first well region.

Preferably, a depth of the second well region is deeper than that of the body contact region.

Preferably, upper surfaces of the body contact region, the source region and the drain region are exposed by the first well region.

Preferably, a lower surface of the gate conductor and an upper surface of the first well region are separated by a gate dielectric layer.

Preferably, an insulating layer is located between the body contact region and the source region, between the body contact region and one side edge of the field effect transistor, and between the drain region and the other side edge of the field effect transistor.

Preferably, an N-well region is located between the substrate and the first well region.

According to another aspect of the present disclosure, there is provided a method for manufacturing a field effect transistor, comprising: forming a first well region of P type on a substrate; forming a second well region of P type in the first well region of P type by P-type ion implantation, wherein an upper surface of the second well region is exposed by the first well region and doping concentration of the second well region is higher than that of the first well region; forming a gate conductor above the first well region of P type; forming a drain region and a source region in the first well region by N-type ion implantation, wherein the drain region and the second well region are separated by the first well region; forming a body contact region by P-type ion implantation, wherein the second well region is at least located between the body contact region and the source region.

Preferably, the method further comprises: forming an insulating layer between the body contact region and the source region, between the body contact region and one side edge of the field effect transistor, and between the drain region and the other side edge of the field effect transistor.

Preferably, a depth of the second well region is deeper than that of the body contact region.

Preferably, a parasitic bipolar junction transistor is located in the field effect transistor, the second well region is configured to reduce resistance of a base region of the parasitic bipolar junction transistor.

Preferably, a breakdown position of the field effect transistor is located at a common boundary between the drain region and the first well region.

The parasitic NPN BJT is included in the FET according to the embodiments of the present disclosure, where the drain region, the source region, and the well region of the FET is equivalent to a collector region, an emitter region and the base region of the parasitic NPN BJT, respectively. The second well region is formed in the first well region, the body contact region of the FET is located in the second well region, and the drain region is located in the first well region. Since doping concentration of the second well region is higher than that of the first well region, meaning that doping concentration of the base region of the parasitic NPN BJT is increased, so that resistance of the base region of the parasitic NPN BJT is reduced, which reduces amplification factor of the parasitic NPN BJT and increases conductive resistance of the parasitic NPN BJT, thus the effect on the FET caused by the holding current of the FET can be weakened, the holding current of the FET can be prevented from flowing to the substrate of the FET, thus avoiding the failure of the field effect transistor function or even burning the field effect transistor, and the service life of the FET can be prolonged.

In preferred embodiments, the source region may be located in the second well region, the gate conductor may be located above the first well region and the second well region, on the premise of ensuring that the breakdown voltage of the FET can be unchanged, the second well region is preferred to be made as large as possible, such that resistance of the base region of the parasitic NPN BJT can be reduced, amplification factor of the parasitic NPN BJT is further reduced, therefore the holding voltage of the FET can be further improved, such that the effect on the FET caused by the holding current of the FET may be further weakened.

The second well region extends deeper than the body contact region or the source region, preferably, the lower surface of the second well region may be close to the lower surface of the first well region, which may further reduce resistance of the base region of the parasitic NPN BJT and reduce amplification factor of the parasitic NPN BJT, thus the effect on the FET caused by the holding current of the FET may be weakened.

Additionally, the drain region of the FET according to the embodiments of the present disclosure is located in the first well region, a doping concentration around the drain region is not increased, such that the holding voltage of the FET can be improved on the premise of ensuring that the breakdown voltage of the FET is unchanged. At the same time, it may also be ensured that area of the FET and other electrical parameters of the FET can be maintained.

### BRIEF DESCRIPTION OF THE DRAWINGS

The above and other objects, advantages and features of the present invention will become more fully understood from the detailed description given hereinbelow in connection with the appended drawings, and wherein:

FIG. 1a is a cross-sectional diagram illustrating a field effect transistor and a parasitic NPN bipolar junction transistor thereof in the prior art;

FIG. 1b is a graphical representation illustrating a snap-back profile of the FET in the prior art;

FIG. 2a is a cross-sectional diagram illustrating a field effect transistor and a parasitic NPN bipolar junction transistor thereof according to a first embodiment of the present disclosure;

FIG. 2b is a graphical representation illustrating a snap-back profile of the FET according to the first embodiment of the present disclosure;

FIG. 2c is a flow diagram illustrating a process for manufacturing the FET according to the first embodiment of the present disclosure;

FIG. 3 is a cross-sectional diagram illustrating a field effect transistor and a parasitic NPN bipolar junction transistor thereof according to a second embodiment of the present disclosure;

FIG. 4 is a cross-sectional diagram illustrating a field effect transistor and a parasitic NPN bipolar junction transistor thereof according to a third embodiment of the present disclosure;

FIG. 5 is a cross-sectional diagram illustrating a field effect transistor and a parasitic NPN bipolar junction transistor thereof according to a fourth embodiment of the present disclosure.

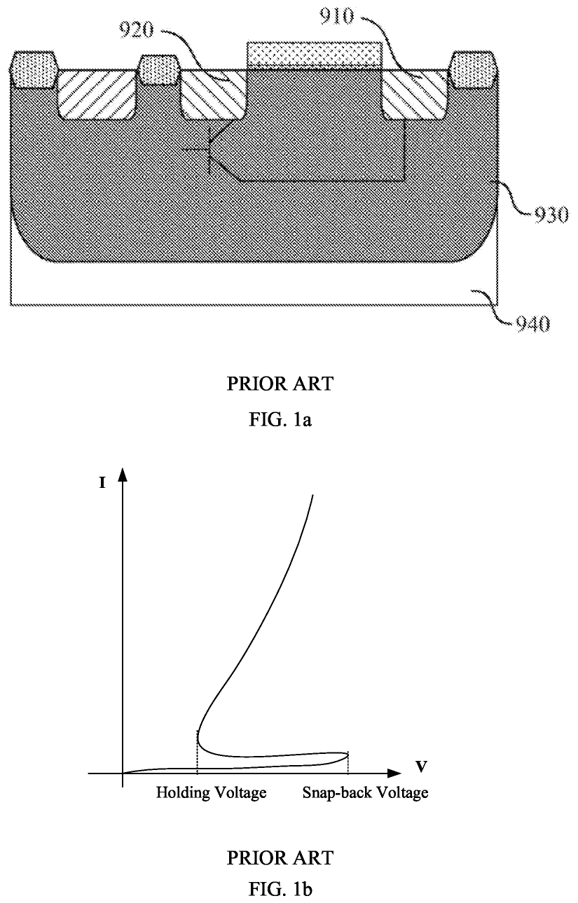

### DETAILED DESCRIPTION OF EMBODIMENTS OF THE DISCLOSURE

Exemplary embodiments of the present disclosure will be described in more details below with reference to the accompanying drawings. In the drawings, like reference numerals denote like members. The figures are not drawn to scale, for the sake of clarity. Moreover, some well-known parts may not be shown. For simplicity, the structure of the semiconductor device having been subject to several relevant process steps may be shown in one figure.

It should be understood that when one layer or region is referred to as being “above” or “on” another layer or region in the description of device structure, it can be directly above or on the other layer or region, or other layers or regions may be intervened therebetween. Moreover, if the device in the figures is turned over, the layer or region will be under or below the other layer or region.

In contrast, when one layer is referred to as being “directly on” or “on and adjacent to” or “adjoin” another layer or region, there are not intervening layers or regions present. In the present application, when one region is referred to as being “directly in”, it can be directly in another region and adjoins the another region, but not in an implantation region of the another region.

Some particular details of the present disclosure will be described below, such as exemplary semiconductor structures, materials, dimensions, process steps and technologies of the semiconductor device, for better understanding of the present disclosure. However, it can be understood by one skilled person in the art that these details are not always essential for but can be varied in a specific implementation of the disclosure.

There is a parasitic bipolar junction transistor (BJT) in a field effect transistor (FET) according to the embodiments of the present disclosure, and the parasitic BJT is of NPN type. Where a drain region, a source region, and a well region of the FET is equivalent to a collector region, an emitter region and a base region of the parasitic NPN BJT, respectively. Due to the presence of the parasitic NPN BJT, a snap-back phenomenon occurs when the FET breaks down, thus a snap-back voltage is generated and the parasitic NPN BJT is turned on when the snap-back phenomenon occurs. At this time, only a relatively low voltage between two terminals corresponding to the source region and the drain region of the FET is required for maintaining a large current flowing through the parasitic NPN BJT, the relatively low voltage is called a holding voltage of the FET, and current generated by parasitic NPN bipolar junction transistor is called a holding current of the FET. The FET of N type is taken as an example here according to the embodiments of the present disclosure.

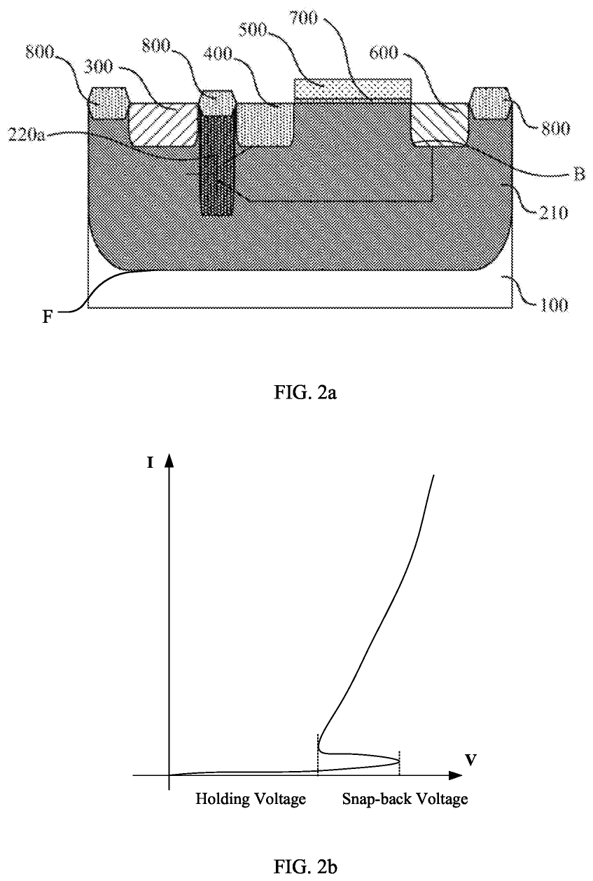

FIG. 2a is a cross-sectional diagram illustrating the FET and the parasitic NPN BJT thereof according to a first embodiment of the present disclosure.

Referring to FIG. 2a, a well region is located on a substrate 100. A body contact region 300, the source region 400 and the drain region 600 are located in the well region, the source region 400 is located between the body contact region 300 and the drain region 600, and a channel is formed between the source region 400 and the drain region 600. The well region comprises a first well region 210 and a second well region 220a. The second well region 220a is located in the first well region 210, the second well region 220a is surrounded by the first well region 210, the second well region 220a extends at least between the body contact region 300 and the source region 400, an upper surface of the second well region 220a is exposed by the first well region 210, and doping concentration of the second well region 220a is higher than that of the first well region 210. Where the substrate 100, the well region and the body contact region 300 is P-type doped, the source region 400 and the drain region 600 is N-type doped. The second well region 220a may extend to its left side and its right side, so that width of the second well region 220a can be increased.

Preferably, the second well region 220a extends to its right side, that is, extends towards the source region 400, and may furthest reach an first side edge of the source region 400, where the first side edge of the source region 400 is adjacent to a first side surface of the gate conductor 500.

Preferably, the body contact region 300 is located in the first well region 210, and the upper surface of the body contact region 300 is exposed by the first well region 210.

At least a portion of a side surface of the source region 400 and at least a portion of a side surface of the body contact region 300 is separated by an insulating layer 800, further, the source region 400 is located in the first well region 210, the upper surface of the source region 400 is exposed by the first well region 210.

The gate conductor 500 is located above the channel between the source region 400 and the drain region 600, specifically, gate conductor 500 is located above at least a portion of the upper surface of the first well region 210 and between the source region 400 and the drain region 600. The lower surface of the gate conductor 500 and the upper surface of the first well region 210 are separated by a gate dielectric layer 700. The gate conductor 500 may be composed of doped polysilicon; the gate dielectric layer 700 may be an oxide layer with a specific thickness, which is, for example, a silicon oxide layer.

The drain region 600 is located in the first well region 210, an upper surface of the drain region 600 is exposed by the first well region 210, and a first side surface of the drain region may be adjacent to a second side surface of the gate conductor 500.

The insulating layer 800 is arranged between the body contact region 300 and edges of the FET, that is, the insulating layer 800 is located at one side of the body contact region 300 away from the source region 400; the insulating layer 800 is also arranged between the drain region 600 and the edges of the FET, that is, the insulating layer 800 is located on one side of the drain region 600 away from the second well region 220a; the insulating layer is also arranged between the body contact region 300 and the source region 400. The insulating layer 800 may be composed of oxide or nitride, e.g., silicon oxide or silicon nitride.

An N-well region may be located between the substrate 100 and the well region, the substrate 100 and the well region are separated by the N-well region.

FIG. 2b is a graphical representation illustrating a snap-back profile of the FET according to the first embodiment of the present disclosure.

There is a parasitic BJT in the FET according to the first embodiment of the present disclosure. The second well region 220a is surrounded by the first well region 210, and the second well region 220a is located at least between the body contact region 300 and the source region 400, the drain region 600 of the FET is located in the first well region 210. Since doping concentration of the second well region 220a is higher than that of the first well region 210, meaning that doping concentration of the base region of the parasitic NPN BJT is increased, so that amplification factor of the parasitic NPN BJT is reduced, which improves the holding voltage of the FET and weakens the parasitic effect, as shown in FIG. 2b, thus the effect on the FET caused by the holding current of the FET can be reduced, the holding current of the FET can be prevented from flowing to the substrate of the FET, therefore the FET is prevented from failure or even being burned out, service life of the FET can be prolonged and product competitiveness can be improved.

The second well region 220a extends deeper than the body contact region 300 or the source region 400. Preferably, the lower surface of the second well region 220a may be close to the lower surface of the first well region 210, which may further reduce the resistance of the base region of the parasitic NPN BJT, thereby further reducing the amplification factor of the parasitic NPN BJT, thus the holding voltage of the FET is further increased, which may further weaken the effect on the FET caused by the holding current of the FET.

The higher the doping concentration of the second well region 220a is, the larger the holding voltage of the FET will be and the smaller effect on the FET caused by the holding current will be. However, if the doping concentration of the second well region 220a is excessively large, second well region 220a may occur an diffusion, which may affect other parameters of the FET. Therefore, doping concentration of the second well region 220a may be selected in accordance with demands of the holding voltage of the FET.

Additionally, according to the first embodiment of the present disclosure, the breakdown of the FET generally occurs at the junction of the drain region 600 and the first well region, shown at position B in FIG. 2a. The breakdown voltage of the FET is typically determined by doping concentration of the drain region 600 and doping concentration of the first well region, and the drain region 600 of the FET is located in the first well region 210, doping concentration of the first well region 210 around the drain region 600 is not increased. So that the holding voltage of the FET is improved on the premise of ensuring that the breakdown voltage of the FET is unchanged. At the same time, it may also be ensured that area of the FET and other electrical parameters of the FET can be maintained.

FIG. 2c is a flow diagram illustrating a process for manufacturing the FET according to the first embodiment of the present disclosure, the process for manufacturing the FET includes following steps.

In step S01, the well region is formed on the P-type substrate 100.

The well region includes a first well region 210 and a second well region 220a, the first well region 210 is formed on the P-type substrate 100, and the second well region 220a is formed in the first well region 210. The well region is formed by P-type ion implantation or other suitable processes, the second well region 220a is surrounded by the first well region 210, and the upper surface of the second well region 220a is exposed by the first well region 210. The doping concentration of the second well region 220a is higher than that of the first well region 210.

In step S02, the gate dielectric layer 700 is formed on the upper surface of the first well region 210, the gate conductor 500 is formed on the gate dielectric layer, thus the lower surface of the gate conductor 500 and the upper surface of the first well region 210 is separated by the gate dielectric layer 700.

In step S03, the source region 400 is formed in the first well region 210, the drain region 600 is formed in the first well region. The source region 400 and the drain region 600 is formed by N-type ion implantation.

The body contact region 300 is formed in the first well region 210 by P-type ion implantation, at least a portion of one side surface of the source region 400 and at least a portion of one side surface of the body contact region 300 is separated by the insulating layer 800.

The upper surfaces of the body contact region 300, the source region 400 and the drain region 600 are exposed by the first well region 210.

The insulating layer 800 is formed between the body contact region 300 and one edge of the FET, and between the drain region 600 and the other edge of the FET.

Where the second well region 220a extends deeper than the body contact region 300, preferably, the lower surface of the second well region 220a may be close to the lower surface of the first well region 210.

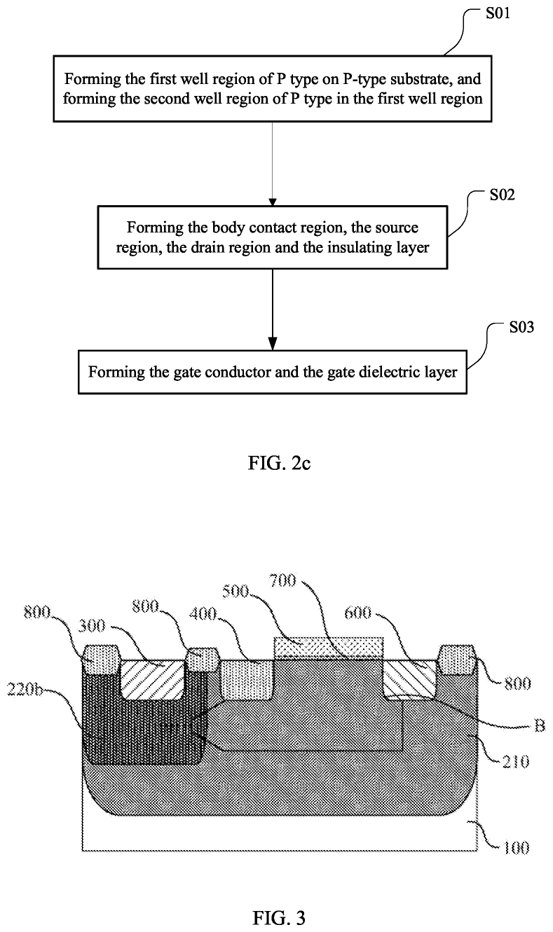

FIG. 3 is a cross-sectional diagram illustrating a field effect transistor and a parasitic NPN bipolar junction transistor thereof according to a second embodiment of the present disclosure. The FETs according to the second embodiment and the first embodiment of the present disclosure are similar to each other, the following mainly introduces differences between them, for clarity of description.

The well region of the FET according to the second embodiment of the present disclosure is located on the P-type substrate; a second well region 220b is located in the first well region 210, the upper surface of the second well region 220b is exposed by the first well region 210. The main differences between the FET referring to FIG. 3 and the FET referring to FIG. 2a at least comprise: the body contact region 300 is located in the second well region 220b, the source region 400 is located in the first well region 210, the gate conductor 500 is located above the first well region 210, meaning that the second well region 220b according to the second embodiment is larger than the second well region 220a according to the first embodiment.

On the premise of ensuring an unchanged breakdown voltage of the FET, that is, the second well region 220b is isolated with position B, the second well region 220b is further expanded, therefore resistance of the base region of the parasitic NPN BJT is reduced, amplification factor of the NPN BJT is reduced, the holding voltage of the FET is further improved, thus further weakening the effect on the FET caused by the holding current of the FET.

The process for manufacturing the FET according to the second embodiment of the present disclosure is similar to the process for manufacturing the FET according to the first embodiment.

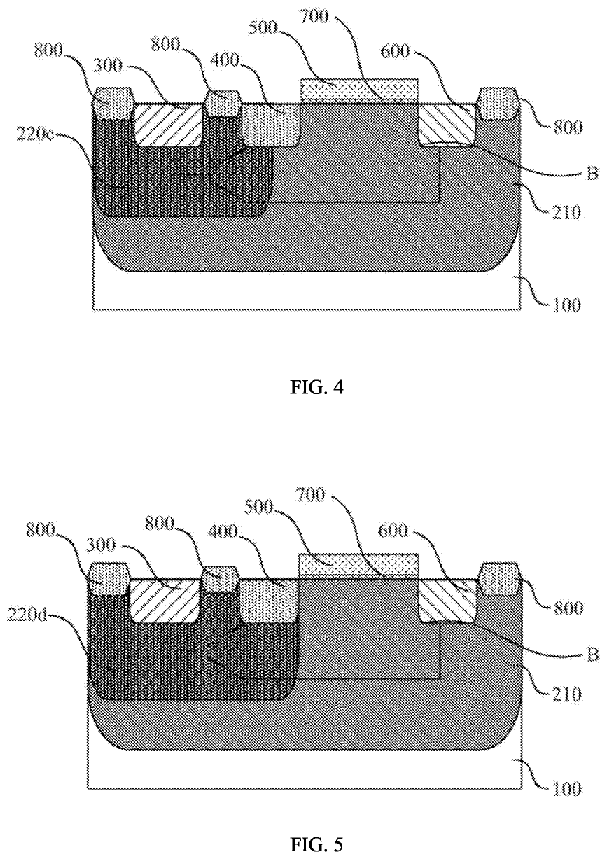

FIG. 4 is a cross-sectional diagram illustrating a field effect transistor and a parasitic NPN bipolar junction transistor thereof according to a third embodiment of the present disclosure. The FETs according to the third embodiment and the second embodiment of the present disclosure are similar to each other, the following mainly introduces differences between them, for clarity of description.

The well region of the FET according to the third embodiment of the present disclosure is located on the P-type substrate; a second well region 220c is located in the first well region 210, the upper surface of the second well region 220c is exposed by the first well region 210. The main differences between the FET referring to FIG. 4 and the FET referring to FIG. 3 at least comprise: the source region 400 is located in the first well region 210 and the second well region 220c, that is, one portion of the source region 400 is located in the first well region 210 and the remaining portion of the source region 400 is located in the second well region 220c, meaning that the second well region 220c according to the third embodiment is larger than the second well region 220b according to the second embodiment.

On the premise of ensuring an unchanged breakdown voltage of the FET, that is, the second well region 220c is isolated with position B, the second well region 220c is further expanded, therefore resistance of the base region of the parasitic NPN BJT is reduced, amplification factor of the NPN BJT is reduced, which may further improve the holding voltage of the FET and further weaken the influence on the FET caused by the holding current of the FET.

The process for manufacturing the FET according to the third embodiment of the present disclosure is similar to the process for manufacturing the FET according to the first embodiment.

FIG. 5 is a cross-sectional diagram illustrating a field effect transistor and a parasitic NPN bipolar junction transistor thereof according to a fourth embodiment of the present disclosure. The FETs according to the fourth embodiment and the third embodiment of the present disclosure are similar to each other, the following mainly introduces differences between them, for clarity of description.

The well region of the FET according to the fourth embodiment of the present disclosure is located on the P-type substrate; a second well region 220d is located in the first well region 210, the upper surface of the second well region 220d is exposed by the first well region 210. The main differences between the FET referring to FIG. 5 and the FET referring to FIG. 4 at least comprise: the source region 400 is located in the second well region 220d completely, the gate conductor 500 is located above the first well region 210, that is, one side surface (near the gate conductor) of the source region 400 and one side surface (near the gate conductor) of the second well region are arranged close to each other, or in a same plane, meaning that the second well region 220d according to the fourth embodiment is larger than the second well region 220c according to the third embodiment.

On the premise of ensuring an unchanged breakdown voltage of the FET, that is, the second well region 220d is isolated with position B, the second well region 220d is further expanded, therefore resistance of the base region of the parasitic NPN BJT is further reduced, amplification factor of the NPN BJT is further reduced, which may further improve the holding voltage of the FET and further weaken the influence on the FET caused by the holding current of the FET.

The process for manufacturing the FET according to the fourth embodiment of the present disclosure is similar to the process for manufacturing the FET according to the first embodiment.

To sum up, on the premise that the second well region located in the first well region 210 does not affect the common boundary between the drain region 600 and the first well region 210, that is, the breakdown voltage of the FET is not influenced, preferably, on the premise that the second well region located in the first well region 210 does not affect the channel of the device, that is, the breakdown voltage and other electrical parameters of the FET are not affected, the larger the horizontal dimension of the second well region is, the larger the holding voltage of the FET will be, the less effect on the FET caused by the holding current will be, thus the service life of the FET is prolonged better.

It should also be understood that the relational terms such as “first”, “second”, and the like are used in the context merely for distinguishing one element or operation form the other element or operation, instead of meaning any real relationship or order of these elements or operations.

Moreover, the terms “comprise”, “comprising” and the like are used to refer to comprise in nonexclusive sense, so that any process, approach, article or apparatus relevant to an element, if follows the terms, means that not only said element listed here, but also those elements not listed explicitly, or those elements inherently included by the process, approach, article or apparatus relevant to said element.

If there is no explicit limitation, the wording “comprise a/an . . . ” does not exclude the fact that other elements can also be included together with the process, approach, article or apparatus relevant to the element.

Although various embodiments of the present invention are described above, these embodiments neither present all details, nor imply that the present invention is limited to these embodiments.

Obviously, many modifications and changes may be made in light of the teaching of the above embodiments. These embodiments are presented and some details are described herein only for explaining the principle of the invention and its actual use, so that one skilled person can practice the present invention and introduce some modifications in light of the invention.

The invention is intended to cover alternatives, modifications and equivalents that may be included within the spirit and scope of the invention as defined by the appended claims.

What is claimed is:

1. A field effect transistor, comprising:
a substrate;
a first well region located on said substrate;
a second well region located in said first well region;
a body contact region, a source region and a drain region, all of which are located in said first well region, wherein said source region is located between said body contact region and said drain region, wherein a channel is formed between said source region and said drain region;
a gate conductor located above said channel between said source region and said drain region;
wherein said substrate, said first well region, said second well region and said body contact region are doped to have a first conductive type, said source region and said drain region are doped to have a second conductive type, a doping concentration of said second well region is higher than that of said first well region, said drain region is located in said first well region,
wherein said body contact region is located in said second well region, said drain region of said field effect transistor is in direct contact with said first well region and is separated from said second well region of said field effect transistor by said first well region.

2. The field effect transistor according to claim 1, wherein a parasitic bipolar junction transistor is located in said field effect transistor, said second well region is configured to reduce resistance of a base region of said parasitic bipolar junction transistor.

3. The field effect transistor according to claim 1, wherein said second well region is at least located between said body contact region and said source region.

4. The field effect transistor according to claim 1, wherein a breakdown voltage of said field effect transistor is regulated by adjusting doping concentration of said first well region, and a holding voltage of said field effect transistor is regulated by adjusting doping concentration of said second well region.

5. The field effect transistor according to claim 1, wherein said first conductive type is one of N type and P type, said second conductive type is the other one of N type and P type.

6. The field effect transistor according to claim 1, wherein a breakdown position of said field effect transistor is located at a common boundary of said drain region and said first well region.

7. The field effect transistor according to claim 1, wherein a portion of said second well region is located between said body contact region and said source region, said source region is located in said first well region, said gate conductor is located above said first well region.

8. The field effect transistor according to claim 1, wherein a first portion of said source region is located in said first well region and a second portion of said source region is located in said second well region, and said gate conductor is located above said first well region.

9. The field effect transistor according to claim 1, wherein said source region is located in said second well region, a side surface of said source region near said gate conductor is close to a side surface of said second well region near said gate conductor, such that said gate conductor is located above said first well region.

10. The field effect transistor according to claim 1, wherein a depth of said second well region is deeper than that of said body contact region.

11. The field effect transistor according to claim 1, wherein upper surfaces of said body contact region, said source region and said drain region are exposed by said first well region.

12. The field effect transistor according to claim 1, wherein a lower surface of said gate conductor and an upper surface of said first well region are separated by a gate dielectric layer.

13. The field effect transistor according to claim 1, wherein an insulating layer is located between said body contact region and said source region, between said body contact region and one side edge of said field effect transistor, and between said drain region and the other side edge of said field effect transistor.

14. The field effect transistor according to claim 1, wherein said field effect transistor further comprises:
an N-well region located between said substrate and said first well region.
